(19) United States
(12) Patent Application Publication
(10) Pub. No.: US 2026/0289060 A1
(43) Pub. Date: Sep. 24, 2026

(54) FLEXIBLE ROW INTEGRATED CIRCUIT (IC) FLOORPLAN

(71) Applicant: Taiwan Semiconductor Manufacturing Company, Ltd., Hsinchu (TW)

(72) Inventors: Sachin Kumar, Austin, TX (US); Vibhav Salimath, Austin, TX (US); Kumar Lalgudi, San Jose, CA (US)

(73) Assignee: Taiwan Semiconductor Manufacturing Company, Ltd., Hsinchu (TW)

(21) Appl. No.: 19/084,062

(22) Filed: Mar. 19, 2025

(51) Int. Cl. G06F 30/392; G06F 30/323

(52) U.S. Cl. CPC G06F 30/392; G06F 30/323

(57) ABSTRACT

An example method for designing an integrated circuit includes generating a first floor plan for an integrated circuit including a first plurality of first rows of a first cell height and a second plurality of second rows of a second cell height. Generating the first floor plan includes organizing the plurality of first rows and the plurality of second rows in a first row pattern. The method further includes modifying the first floor plan based on a predetermined cell density of first cells having the first cell height and second cells having the second cell height to generate a second floor plan. Modifying the first floor plan includes organizing the plurality of first rows and the plurality of second rows in a second row pattern. The second row pattern has X′ first rows and Y′ second rows where X′ and Y′ are positive integers.

### BACKGROUND

In an electronic circuit design process, one or more electronic design automation (EDA) tools may be utilized to design, optimize, and verify semiconductor device designs, such as circuit designs in a semiconductor chip. EDA can be divided into a series of stages such as synthesis, placement, routing, etc. EDA begins from a functional specification provided in a hardware description language (HDL) and continues through the specification of a circuit design including the specification of elementary circuit components called cells, the physical arrangement of the cells, and the wiring that interconnects the cells. The cells implement logic or other electronic functions using a particular integrated circuit technology. The first task in physical design is floor planning, which determines memory macro locations to optimize high-level circuit module locations. Usually, cells in a floor plan are arranged in rows and columns. Many designs currently use fixed row ratios that are fixed at the floor planning stage.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 illustrates a block diagram schematically showing example regions of an integrated circuit.

FIG. 2 illustrates an example region with a fixed row region and a variable row region of the integrated circuit of FIG. 1.

FIG. 3 illustrates an example method for optimizing a floor plan of the integrated circuit.

FIG. 4 illustrates an example method for generating variable rows.

FIG. 5 illustrates an example region generated using the method of FIG. 4.

FIG. 6 illustrates an additional example method for generating variable rows.

FIG. 7 illustrates an example region generated using the method of FIG. 6.

FIG. 8 illustrates an additional example method for generating variable rows.

FIG. 9 illustrates an example region generated using the method of FIG. 8.

FIG. 10 illustrates an additional example method for generating variable rows.

FIG. 11 illustrates an example region generated using the method of FIG. 10.

FIG. 12 is a block diagram illustrating an example of a processing system in accordance with some embodiments.

FIG. 13 is an example semiconductor device manufacturing system.

FIG. 14 is an example integrated circuit design and fabrication process.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Electronic Design Automation (EDA) tools and methods facilitate the design, partition, and placement of microelectronic integrated circuits (IC) on a semiconductor substrate. This process typically includes turning a behavioral description of the circuit into a functional description, which is then decomposed into logic functions and mapped into cells using a standard cell library. Once mapped, a synthesis is performed to turn the structural design into a physical layout, a clock tree is built to synchronize the structural elements, and the design is optimized post layout.

As previously mentioned, a first step of IC design is floor planning. Floor planning involves the strategic arrangement of major functional blocks within the chip area. This “blueprint” guides the placement of essential components, including standard cells, macros, and input/output (I/O) pads, ultimately influencing die size, routing, and overall performance.

After floor planning, the design will go through placement and routing stages. During placement, a placer tool may produce a placement layout based on a given circuit design, which may be developed by a circuit designer, and which may include, for example, circuit design information such as electrical diagrams, high level electrical description of the circuit design, a netlist, or the like. The placement layout includes information indicating physical positions of various circuit elements of the semiconductor device. After the placement of the device is completed, routing may be performed. During routing, wires or interconnections may be formed to connect the various circuit elements of the placement layout. After routing, the resulting electronic device designs are checked for compliance with various design rules, design specifications, or the like. A netlist is a description of the connectivity of an electronic circuit. The netlist specifies the components in the circuit and the connections between them.

Some IC designs are based on a collection of cells selected from a library. The layout includes at least one logic block customized for a particular use. A logic block is an arrangement of cells placed in a routing grid of vertical and horizontal routing tracks. Conductive structures, such as metal lines, are placed on routing tracks to provide connection between cells. The design of an IC layout is carried out by an automatic placement and routing (APR) tool that includes a placer and a router, by selecting standard cells from a library of standard cells and placing and routing the cells according to a number of design rules. The placer determines the optimum location of each standard cell of the integrated circuit, and the router optimizes the routing of input/output lines and the connection between standard cells so that the IC layout does not become overly congested by input/output and other routing lines.

The placer and router use a number of design rules to determine where to place the cells and how to create the wires to connect all the cells. The design rules for example, include minimum length of lines, minimum spacing between lines, and the like. Failure to satisfy a design rule sometimes results in a process-related problem such as shorting between meal lines due to optical proximity, in some instances.

The height of a cell is determined by the number of horizontal tracks extending between the uppermost and lowermost edges of the cell. Cells with a smaller cell height are used for realizing high integration and low power consumption, while cells with a higher cell height are used for high-speed operation. In some logic blocks, the standard cells have a same cell height for easy cell placement and routing. In some embodiments, cells share the same width, or the cells have different widths. In some examples, cells with a low threshold voltage have relatively high speed and power but may require additional manufacturing steps. In some embodiments, cells with a relatively high threshold voltage design may use less power, but also may have lower speed as compared to low threshold voltage cells while still requiring additional manufacturing steps.

Some integrated circuits include a first row having a first height with cells in the first row that have the first height, and a second row having a second height. Cells in the second row have the second height.

In traditional IC design, standard cells (e.g. pre-designed logic gates) are placed in rows of uniform height. These rows are then separated by routing channels for interconnections. In contrast, a hybrid row cell design using standard cells of different cell heights in one logic block helps to achieve both high speed and low power in an integrated circuit layout design. Hybrid row designs have row balancing criteria to avoid row density balances in the design. In chip design, density refers to the number of circuit elements (such as cells) per area on a chip. Each cell may have an individual density that refers to the number of specific cell type per area on the chip. Further, each cell height may also include a specified density that refers to the number of rows that accommodate the specified cell height per cell area. Desired densities for different cell heights may be desired and used to balance rows.

An integrated circuit hybrid row design is provided in various embodiments. The hybrid row design provides balanced variable row pattern regions in the floor plan of an IC. Further, the row design provides improved row balancing using native composition of a netlist, extra rows for local timing/density criteria, and placement flexibility in area/regions of the floor plan. The row regions may be created after initial synthesis and placement of basic row patterns in a region of the integrated circuit. Accordingly, initial synthesis and placement is completed using native composition of the netlist and without any row balancing in some embodiments. Modified row patterns may then be placed in the region using an incremental placement optimization process. The modified row patterns are then finalized. In some embodiments, the modified row patterns and regions are generated in the floor plan based on cell density, a congestion map, a region/area timing, or design hierarchies.

The IC hybrid row design may be implemented using IC fabrication tools. In some embodiments, the modified rows of the hybrid row design of the present disclosure are based on native composition of the netlist. As a result, the hybrid row design has a low impact on row criteria for quality of results (QOR). In some embodiments, timing critical hierarchies benefit from having taller and faster cells in close vicinity due to creation of extra rows. Non-timing critical hierarchies may use short cells and may be placed together with higher density. Further, the hybrid row design may only modify a row distribution of a region in the integrated circuit without changing design area since the variable row regions are created inside an existing floor plan of the integrated circuit. Further, the IC hybrid row design provides flexibility in area and region generation of the floor plan.

In some embodiments, methods for optimizing cell or row placement are provided. A floor plan may be generated, and rows synthesized with basic row patterns that are fixed. Then, flexible modified rows are created. Further, lower layers may be rerouted based on the modified rows. Further, the modified rows may be checked for density rules and other criteria, such as QOR criteria. Then, the modified rows are placed using placement optimization.

In some embodiments, methods for generating modified rows for a region of an IC are provided. The modified rows may be generated using uniform row patterns with cells that have variable row patterns. In some embodiments, the modified rows are generated using predetermined row patterns. In some embodiments, the modified rows are generated using non-uniform row patterns with cells that have variable row patterns.

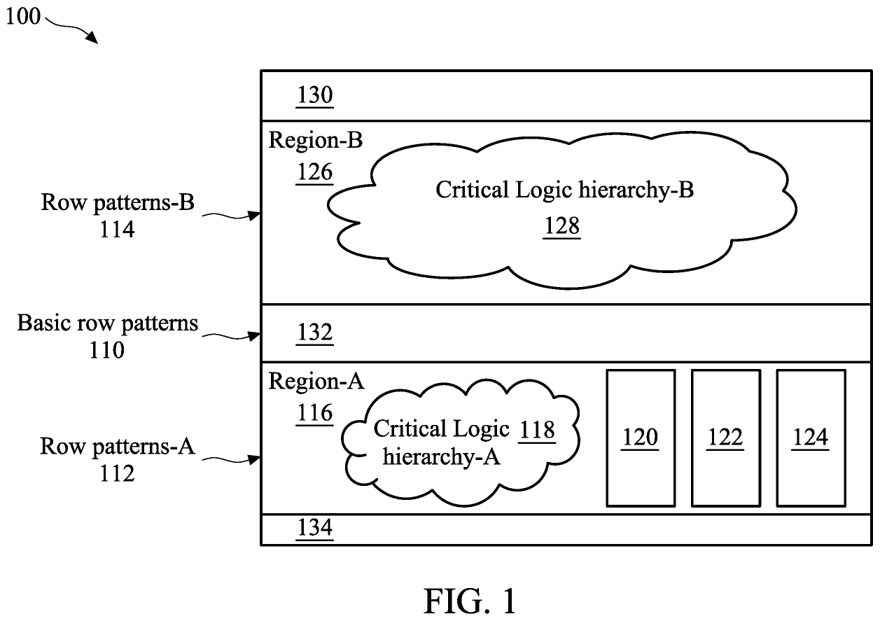

FIG. 1 a block diagram schematically showing example regions of an IC 100. In this embodiment, the IC 100 includes a region A 116, a region B 126, a region 130, a region 132, and a region 134. The region A 116 includes row patterns A 112, and the region B 126 includes row patterns B 114. The IC 100 also includes basic row patterns 110. The region A 116 includes a critical logic hierarchy A 118, and the region B 126 include a critical logic hierarchy B 128. The region A also includes a macro 120, a macro 122, and a macro 124.

The IC 100 is a circuit that can be used for various computing or electronic purposes. The IC 100 may be a microchip, which is a miniature electronic circuit etched onto a small piece of semiconductor material, such as silicon. Microchips can contain numerous components like transistors, resistors, and capacitors, all interconnected to perform specific functions. The IC 100 may be used in a processor or microprocessor that executes instructions, performs calculations, and/or controls the flow of data. In some embodiments, the IC 100 may be used as a memory chip that stores information, either temporarily or permanently. For example, the IC 100 may be used in a static random-access memory (SRAM) or a dynamic random-access memory (DRAM). In some embodiments, the IC 100 is used to amplify signals, control devices as controllers, or perform logic operations. In some embodiments, the IC 100 includes additional regions not shown. In some embodiments, the cells have the same width.

In the shown embodiment, the IC 100 includes the region 130, the region 132, and the region 134 that have basic row patterns 110. The basic row patterns 110 are fixed row patterns. Fixed row patterns are row patterns where an X number of first rows equals a Y number of second rows (X and Y are positive integers) where the first and second rows are adjacent to one another. For example, the basic row patterns 110 include a plurality of first rows of a first cell height and a plurality of second rows of a second cell height. The plurality of first rows and plurality of second rows are organized in X zones and Y zones. The X zone and the Y zone may be placed adjacent to one another to form an X/Y pattern that is a ratio of the number of X rows to the number of Y rows. For basic row patterns 110, X and Y may equal each other such that the X:Y ratio is 1:1, or a 1:1 row pattern. Other embodiments thus may include a 2:2 row pattern, a 3:3 row pattern, a 4:4 row pattern, and so on. The region 130, the region 132, and the region 134 may share the same fixed row pattern. Further, the basic row patterns 110 include cells with uniform height. Further, the basic row patterns 110 include cells with uniform height.

In addition, the row patterns A 112 and the row patterns B 114 include variable row patterns. Variable row patterns include variable rows that include cells that vary in the number of rows that are adjacent to one another. For example, the row patterns A 112 and the row patterns B 114 may include the plurality of first rows of the first cell height and a plurality of second rows of the second cell height. Similarly to the fixed rows, the plurality of first rows and plurality of second rows are organized in X zones and Y zones, where X is a positive integer indicating a number of first rows in the X zone, and Y is a positive integer indicating a number of second rows in the Y zone. The X zone and the Y zone may be placed adjacent to one another. In some examples, X+Y. In other words, the rows may be arranged to form a pattern where the number of first rows is different than the number of second rows. For example, the rows may be arranged in patterns where the ratio of X:Y rows varies, such as a 1:2 row pattern, a 1:3 row pattern, a 1:4 row pattern, a 2:3 row pattern, a 2:4 row pattern, a 3:4 row pattern, or the like.

The region A 116 includes critical logic hierarchy A 118 that describes the arrangement and prioritization of cells within the region A 116. Cells within a particular region may be prioritized to increase performance of the integrated circuit. Further, the critical logic hierarchy A 118 and the critical logic hierarchy B 128 may be designed to optimize timing of the circuit. In some embodiments, critical logic hierarchy A 118 and the critical logic hierarchy B 128 may include a critical path that is the longest path in terms of propagation delay between an input signal and an output signal of the IC 100. In some embodiments, the critical logic hierarchy A 118 and the critical logic hierarch B 128 include placing cells with taller heights, such as above a predetermined threshold height, in close vicinity to one another due to the cells heights. This may be due to the need for the creation of extra rows for the taller cells. The region A 116 may also include the macros 120, 122 and 124. These regions could contain, for example, memory macros or other functional circuits.

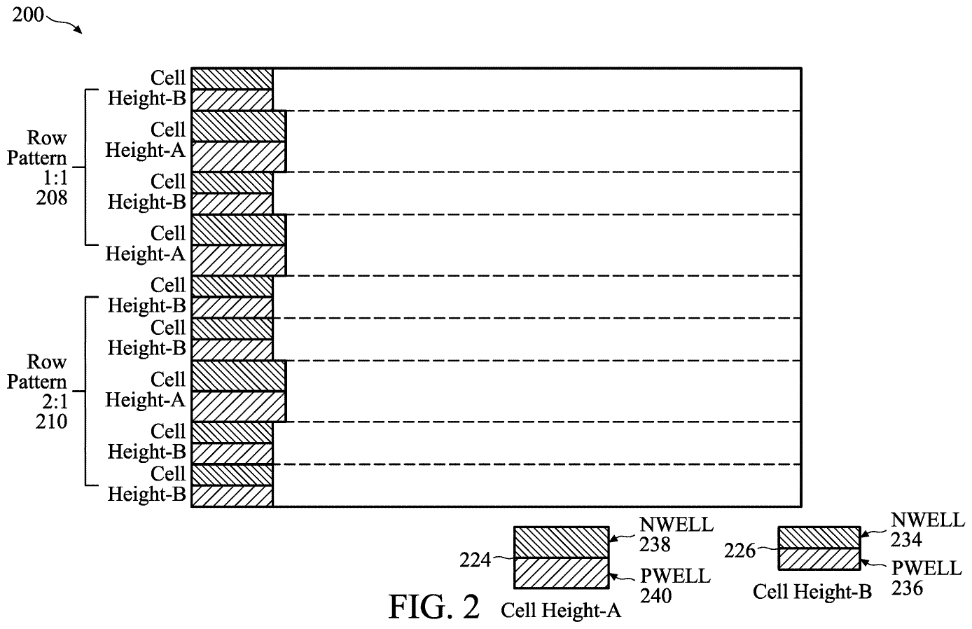

FIG. 2 illustrates further aspects of an example of the IC 100. In FIG. 2, the IC 100 includes a first row region 208 and a second row region 210. The first row region 208 has a 1:1 row pattern, where there is one cell height-B row for each cell height-A row, in other words, a 1:1 ratio of X cell height-B rows to Y cell height-A rows. The second row region 210 has a 2:1 row pattern, where there are two cell height-B rows for each cell height A row. In the example shown in FIG. 2, each of the cells of the cell height-A rows include an NWELL region 234 and a PWELL region 236, and the cells of the cell height-B rows include an NWELL region 238 and a PWELL region 240.

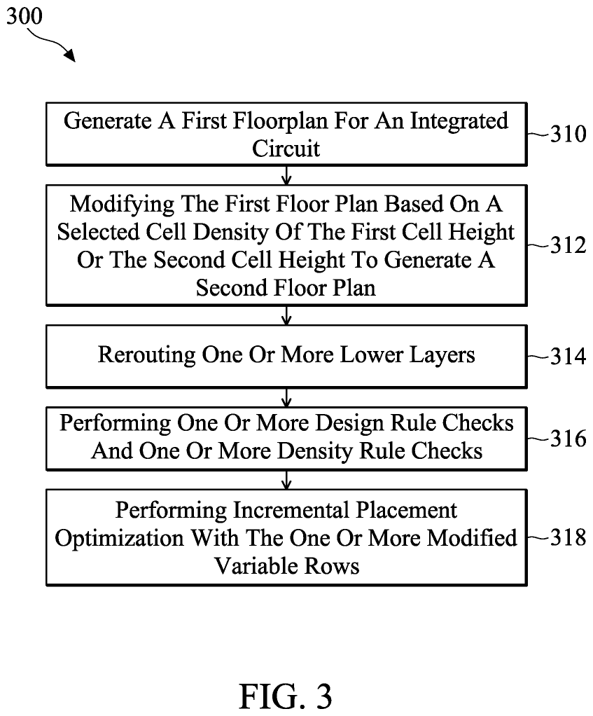

FIG. 3 illustrates an example method 300 for optimizing a floor plan of the IC 100. The method 300 includes an operation 310, an operation 312, an operation 314, an operation 316, and an operation 318. The method 300 can be used to generate an optimized floor plan for the IC 100 or an individual region of the IC 100. The floor plan may include generated row regions that include fixed rows, variable rows, or both. The method 300 may be performed by a circuit fabricator system.

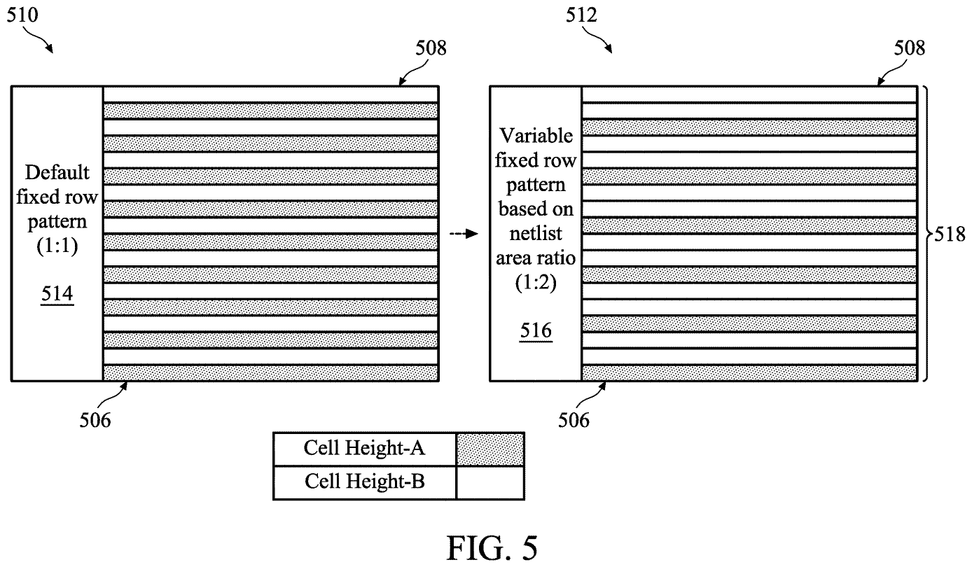

The method 300 may be used to generate the example second floor plan 512 of FIG. 5. FIG. 5 illustrates an example first floor plan 510 being modified to generate the second floor plan 512. The first floor plan 510 includes a 1:1 row pattern 514 that shows the ratio of a plurality of first rows 506 of the first cell height A to a plurality of second rows 506 of the second cell height B for the first floor plan 510. The second floor plan 512 includes a 1:2 row pattern 516 that shows the ratio of first rows of the first cell height A to the second rows of the second cell height B for the first floor plan. The second floor plan 512 includes one or more modified rows 518 that indicate the plurality of first rows 506 and the plurality of second rows 508 placed according to the row pattern 516.

Referring to FIG. 3 and FIG. 5, at the operation 310, the first floor plan 510 is generated for the IC 100, the first floor plan 510 for the IC 100 includes the first plurality of first rows 506 of the first cell height A and the second plurality of second rows 508 of the second cell height B. Generating the first floor plan at operation 310 includes: organizing the plurality of first rows 506 and the plurality of second rows 508 in a first row pattern. The first row pattern has X first rows 506 and Y second rows 508. In the floor plan 510, X=1 and Y=1 such that the first row pattern has a ratio of 1 first row to 1 second row, or a 1:1 pattern. In some embodiments, the ratio may be 2:2, 3:3, 4:4 or other ratios where X and Y>1 and X=Y.

In some embodiments, the IC 100 including the second floor plan 512 is created based on a cell library. The cell library contains a listing of pre-designed components, or functional cells, each of which may perform a predetermined function. The cells are stored in the cell library as information comprising internal circuit elements, the various connections to these circuit elements, a pre-designed physical layout pattern that includes the unit height of each cell along with the cell's designed power rails, dopant implants, wells, etc. Additionally, the stored cell may also comprise a shape of the cell, terminal positions for external connections, delay characteristics, power consumption, etc. The synthesis results in a functionally equivalent logic gate-level circuit description, such as a gate-level netlist. The cell library may be stored, for example, in one or more databases contained in a mass storage. Based on the gate-level netlist, a photolithographic mask may be generated, which is used to fabricate the IC 100. Synthesis may include determining a maximum allowable area for the design, and more particularly, includes calculating the maximum allowable area for each cell type.

Further, synthesis may include calculating a maximum area for a first cell type cell having a first height. This operation is repeated for each of the cell types, so the maximum areas for each cell type having corresponding unit heights are calculated.

In some examples, a design floor plan is determined that includes a plurality of rows into which the standard cells are arranged. The floor plan provides the layout for an integrated circuit, such as would be manufactured according to the method shown in FIG. 3. As such, the generated floor plan illustrates the arrangement of functional cells in rows on a substrate.

At the operation 312, the first floor plan 510 is modified based on a selected cell density of the first cell height A or the second cell height B to generate the second floor plan 512. Modifying the first floor plan 510 may include organizing the plurality of first rows 506 of the first cell height A and the plurality of second rows 508 of the second cell height B in the second row pattern 516. The second row pattern 516 has X′ first rows and Y′ second rows where X′ and Y′ are positive integers. The Y′ second rows are placed in a Y′ zone that is placed adjacent to the X′ first rows. In some embodiments, the X′>1 and the X′ first rows are placed in an X′ zone adjacent to the Y′ zone. In the shown embodiment, X′=1 and Y′=2 to define an X′:Y′ ratio or pattern of 1:2. Accordingly, a single first row of cell height A is placed for every two second rows of cell height B. This 1:2 pattern then repeats.

In other embodiments, the second row pattern 516 may be something other than a 1:2 ratio, such as 1:3, 1:4, 2:3, 2:4, or 3:4, or other row patterns that can be placed in the IC 100. These row patterns indicate ratios of placed first rows of the plurality of first rows 506 of the first cell height A to placed second rows of the plurality of second rows 508 of the second cell height B. In some embodiments, first floor plan 510 may be modified based on the native composition of the netlist. In some embodiments, the plurality of first rows 506 and the plurality of second rows 508 are balanced without modifying the native composition of the netlist. The second floor plan 512 may be generated based on cell density, a congestion map of the region, timing criteria for the area or region of the IC 100, or design hierarchies. The design hierarchies may be received from an external source indicating the desired hierarchy for placement of cells in the IC 100. In some embodiments, the second floor plan 512 is generated iteratively.

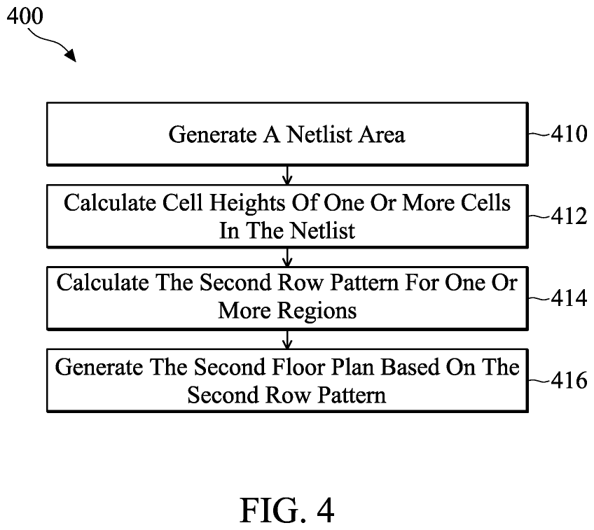

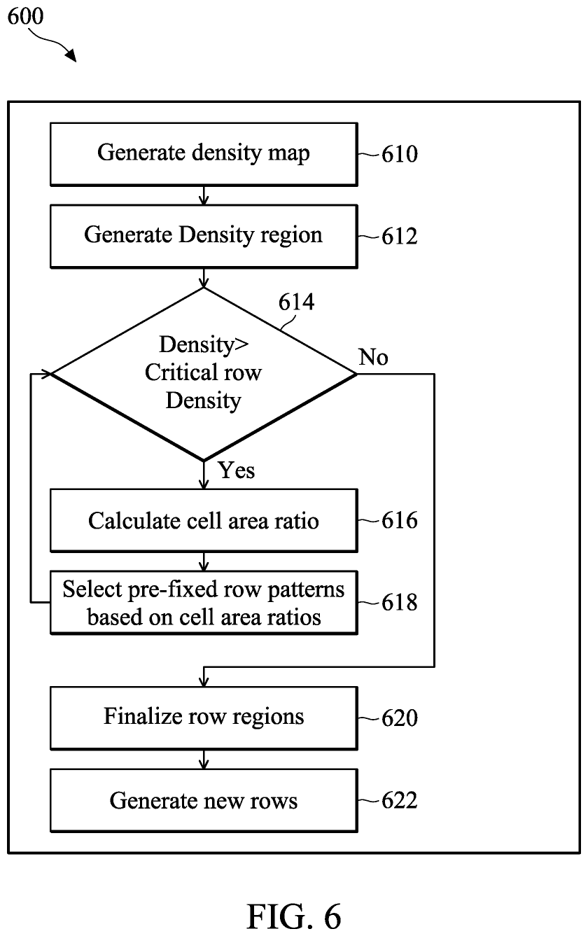

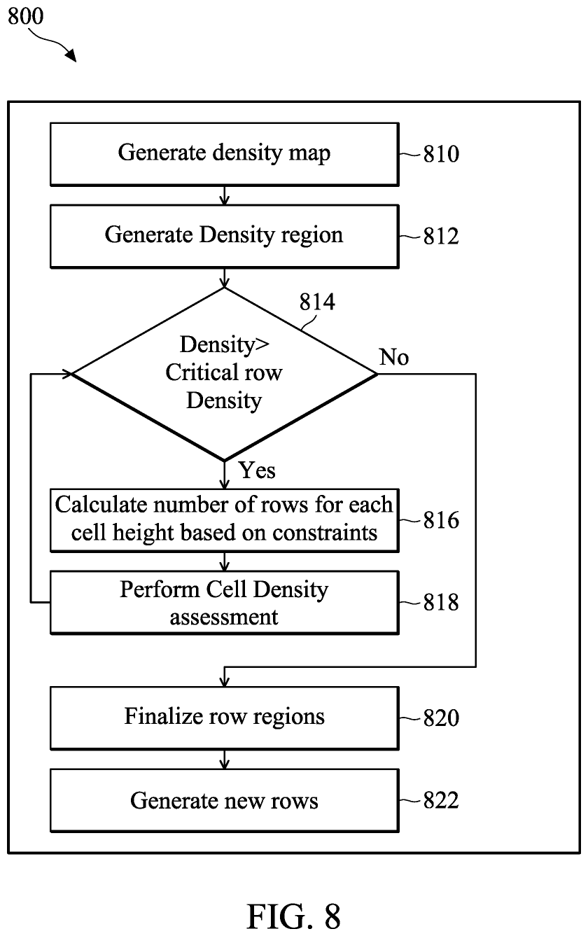

In some embodiments, first floor plan 510 is modified based on a netlist area distribution. The second floor plan 512 includes a uniform row pattern with variable number of rows for different cell heights. In some embodiments, the second floor plan 512 is generated with non-uniform row patterns with pre-fixed row pattern ratios. Pre-fixed row patterns are selected based on calculated row pattern ratios for the region. In some embodiments, the second floor plan 512 is generated with non-uniform row patterns. The second floor plan 512 may be generated based on a local density of the region. In some embodiments, the second floor plan 512 is generated using the methods shown in FIG. 4, FIG. 6, or FIG. 8.

At the operation 314, one or more lower layers are rerouted. Other layers may be rerouted as well. In some embodiments, rerouting the lower layers is based on the placed plurality of first rows 506 and the placed plurality of second rows 508 of the second floor plan 512. Generating the second floor plan 512 may result in the connections needing to be changed. In some embodiments, the power grid PG is rerouted based on the second floor plan 512 due to connections being altered from modifying the row patterns and placement of the rows. In some embodiments, rerouting is completed using manual rerouting or automated rerouting, which uses an EDA tool to analyze the power grid and make changes to improve its performance.

At the operation 316, one or more design rule checks is performed. Design rule checking (DRC) verifies if a specific integrated circuit layout meets the manufacturing constraints of the chosen fabrication process. DRC checks the layout against a set of “design rules” provided to the fabrication system. These rules define geometric constraints like minimum widths, spacing between wires, and minimum areas for different layers of the chip. For example, DRC may include checking for minimum width for wires, minimum spacing between blocks or cells, and a minimum area for selected cells.

In some embodiments, density rule checks ensure each cell meets specified cell area criteria and density criteria. For example, some regions may require a density of multiple cells, accordingly, the cell includes a specified height, area, and/or number of cells to meet the density criteria. In some embodiments, density rule checks ensure the IC 100 or the region meet QOR criteria or timing criteria. The density rule checks may also ensure the IC 100 or the region have a required density of cells. In some embodiments, the areas is measured in micrometers.

Proceeding to the operation 318, incremental placement optimization is performed with the second floor plan 512. Incremental placement may include placing the plurality of first rows 506 and the plurality of second rows 508 to optimize performance of the IC 100. In some embodiments, incremental placement includes placing the plurality of first rows 506 and the plurality of second rows 508 in varying positions in different layouts to form different ratios. Then, the IC 100 can be tested for performance. This process is incrementally done until an optimized IC 100 is realized. In some embodiments, incremental placement includes iteratively changing the row pattern 516 of the second floor plan 512 until a desired performance metric is reached or specified criteria is met.

FIG. 4 illustrates an example method 400 for generating variable rows of the second floor plan 512 to modify the first floor plan 510. The method 400 provides example additional steps performed in conjunction with the operation 312. The method 400 includes an operation 410, an operation 412, an operation 414, and an operation 416. The method 400 may be used to generate the second floor plan 512 with uniform row patterns based on a netlist area distribution to form the second floor plan 512. The method 400 may be performed by a circuit fabricator system.

At operation 410, a netlist area is generated. The netlist area may be generated based on a received netlist composition for the IC 100. Further, the netlist may used to generate one or more regions of the second floor plan 512. The netlist area may indicate a total area for a region or the second floor plan 512. The netlist area may include the total area occupied by the cells of the first cell height A and cells of the second cell height B within a region or the entire second floor plan 512. In some embodiments, the netlist area includes a floor plan size of the second floor plan 512. The floor plan size may equal dividing a summation of the netlist area of a first cell A and the netlist area of a second cell B by a target utilization. For example a netlist area of the first cell height equals Netlist AreaA, a netlist area of the second cell height equals Netlist AreaB, a target utilization equals TU. The Second floor plan size then equals

$$Second Floor Plan Size = \frac{( Netlist AreaA + Netlist AreaB )}{T U}$$

In some embodiments, the target utilization is a specified percentage of the available area on a chip that will be occupied by the placed components (standard cells, macros, etc.) after the placement stage of physical design. The target utilization may be determined based on area efficiency, routability, timing performance, or power consumption.

At operation 412, cell areas for each height in the netlist are calculated. For example, a first cell height A and a second cell height B may be calculated based on the netlist area. In some embodiments, the cell areas for each cell height are calculated based on the received netlist area. The cell area may be calculated based on a selected width for the cell multiplied by the height. In some embodiments, the native composition of the netlist is unchanged. In some embodiments, the netlist includes a maximum cell area for each cell height.

At operation 414, the second row pattern 516 is calculated. The second row pattern 516 indicates the number of rows for the first cell height A and a number of rows of the second cell height B in the second floor plan, as previously discussed. The second row pattern 516 can be calculated for the one or more regions of the IC 100 based on calculated cell height and/or area. In some embodiments, there are one or more row patterns for one or more regions. The row pattern 516 may be calculated by dividing the netlist area of a first cell A by the netlist area of a second cell B.

At operation 416, one or more modified rows 518 are generated. The one or more modified rows 518 may be generated based on the second row pattern 516 that was previously calculated. As a result, balanced rows are placed without modifying the native composition of the netlist. Generating the one or more modified rows 518 may then be used to perform the operation 312. In some embodiments, the one or more modified rows 518 are placed according to a uniform row pattern with different number of rows per cell type of the second row pattern 516. For example, the one or more modified rows 518 may modify the first floor plan 510 to instead have a row pattern of a 1:2, where a row with a first cell height A is adjacently placed next to two rows with a second cell height B. The pattern is then repeated.

In some embodiments, the method 400 includes verifying row balancing of the second floor plan 512. Verifying row balancing may include using a selected density or a utilization ratio threshold. The selected density may be a critical row density threshold as discussed in association with FIG. 6. In some embodiments, the selected density is a specified number of cells that are placed adjacent to one another. If the density of the second floor plan 512 exceeds the selected density, then the circuit may not be verified and needs further row balancing. In some embodiments, the utilization ratio threshold indicates a specified amount of utilization for the IC 100 by cells or macros. If generating and placement of the one or more modified rows results in the cell placement exceeding the utilization threshold, then the circuit may need further row balancing. In some embodiments, the row pattern is incrementally changed and tested to determine if the one or more modified rows 518 are adequately balanced.

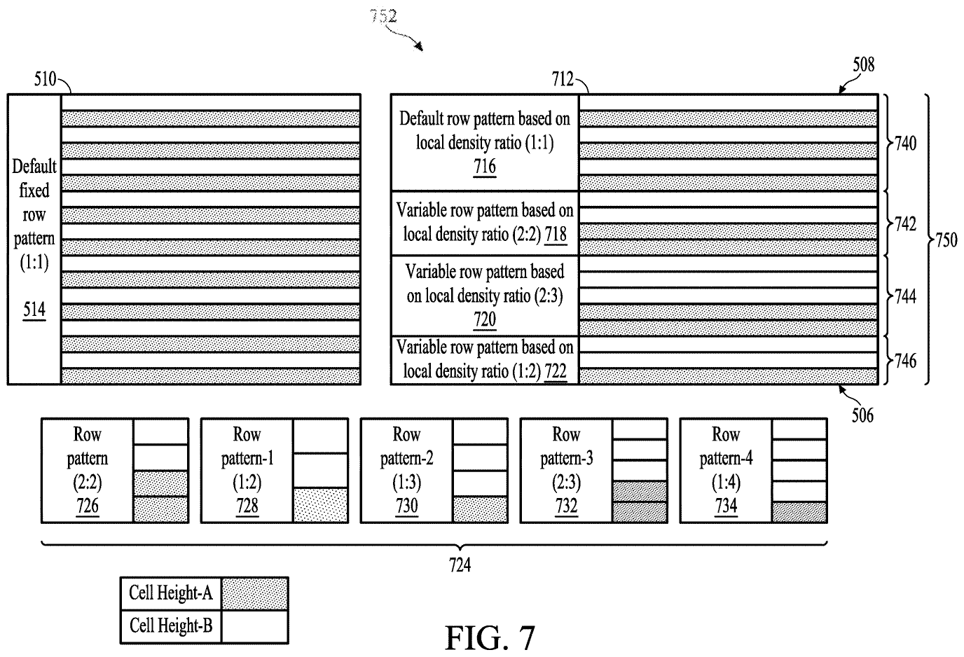

FIG. 6 illustrates an additional example method 600 for generating a second floor plan 712 as shown in FIG. 7. The method 600 may be performed as further operations of the operation 312. In this embodiment, the method 600 includes an operation 610, an operation 612, an operation 614, an operation 616, an operation 618, an operation 620, and an operation 622. The method 600 may be used to generate the second floor plan 712 with non-uniform row patterns with different number of rows for each cell height based on one or more pre-fixed row patterns. The method 600 may be performed by a circuit fabricator system.

FIG. 7 further shows the second floor plan with a local region 740, a local region 742, a local region 744, and a local region 746. The local region 740 includes a row pattern 716, the local region 742 includes a row pattern 718, the local region 744 includes a row pattern 720, and the local region 746 includes a row pattern 722. Further, the second floor plan 712 is formed using a plurality of pre-fixed row patterns 724. The plurality of pre-fixed row patterns 724 includes a pre-fixed row pattern 726, a pre-fixed row pattern 728, a pre-fixed row pattern 730, a pre-fixed row pattern 732, and a pre-fixed row pattern 734. The second floor plan 712 also includes one or more modified rows 750 including the plurality of first rows 506 and the plurality of second rows 508 placed according to the row pattern 716, the row pattern 718, the row pattern 720, and the row pattern 722.

At the operation 610, a density map is generated. The density map may be associated with an integrated circuit, such as the IC 100. The density map may provide selected densities for regions of the IC 100. In some embodiments, the density map indicates how densely regions of the IC 100 are packed with different features, such as rows of cells. In some embodiments, a congestion map is also generated. The congestion map indicates placement of routing resources. Further, the congestion map may indicate where routing resources are in high demand or insufficient for the IC 100.

At the operation 612, a density region is generated. The density region indicates the density for the selected region, such as the first floor plan 510. Generating density regions allows for densities of the IC 100 to be assessed. Further, the density region may include a critical row density threshold (also referred to as the selected density). The critical row density threshold indicates a predetermined or selected density for each cell in the region. Further, the critical row density threshold may indicate a maximum or minimum number of rows a cell of the first cell height A or a cell of the second cell height B can occupy. For example, the critical row density may be a 50% utilization of the area of the floor plan by a selected cell or selected cell type.

At the operation 614, the density of the first floor plan 510 is checked to determine whether the density is greater than the critical row density threshold. The density may include the number of rows for each cell within the region of the IC 100. In some embodiments, a different metric may be used. In some embodiments, the density region is generated to verify the row density of the plurality of first rows 506 and the plurality of second rows 508 of the first floor plan 510. The density region may be based on a user specified number of rows, a user specified cell height, one or more pre-fixed variable row patterns, or any combination. In some embodiments, the critical row density threshold may be 50%, 60%, 70%, or some other specified percentage. In some embodiments, the critical row density threshold includes a maximum area for a cell type or a maximum number of rows for a cell type, or a maximum number of cells for a cell type.

At the operation 616, one or more row patterns 752 including the row pattern 716, the row pattern 718, the row pattern 720, and the row pattern 722 are calculated to modify the first floor plan 510 and generate the second row floor plan 712. The one or more row patterns 752 may be calculated for modifying the first floor plan 510 responsive to a determination that the density of the first floor plan 510 is greater than the critical row density threshold. In some embodiments, the one or more row patterns 752 are calculated by dividing a first cell height A by a second cell height B. The one or more row patterns 752 may include a different number of rows for the first cell height A and the second cell height B. Each ratio may indicate a row pattern for a local portion of the second floor plan 712 of the IC 100, such as the local region 740, the local region 742, the local region 744, and/or the local region 746. The one or more row patterns 752 may be non-uniform. That is, the row pattern 716, the row pattern 718, the row pattern 720, and the row pattern 722 may not equal each other. Further, the one or more row patterns may result in the second floor plan 712 being under the critical row density threshold. Accordingly, the region may become compliant if the one or more modified rows 750 of each of the local region 740, the local region 742, the local region 744, and the local region 746 are changed to rows placed according to the one or more row patterns 752.

At the operation 618, one or more pre-fixed row patterns of the plurality of pre-fixed row patterns 724 are selected based on the one or more row patterns 752. The one or more pre-fixed row patterns may include any number of the plurality of row patterns 724, such as the pre-fixed row pattern 726, the pre-fixed row pattern 728, the pre-fixed row pattern 730, the pre-fixed row pattern 732, and the pre-fixed row pattern 734. For example, the pre-fixed row pattern 728 includes one row of the first cell height A and two rows of the second cell height B in a Y′ zone. The one row of the first cell height A and the Y′ zone are placed adjacently to form the 1:2 pattern. The one or more pre-fixed row patterns 724 are used to fill in the local region 740, the local region 742, the local region 744, and the local region 746 with a pre-fixed row pattern that includes a corresponding row pattern to the determined one or more row patterns 752. For example, if four local portions of a region were determined to have row patterns of 1:1, 2:2, 2:3, and 1:3. Then pre-fixed row patterns with row patterns of 1:2, 1:3, 2:3, and 1:3 are selected for placement in the second floor plan 712 when fabricating the IC 100 as shown in FIG. 7. The one or more pre-fixed row patterns can be placed accordingly to form a desired X′:Y′ ratio. The pre-fixed row patterns can include any variation of X′:Y′ where X′:Y′ are positive integers. X′ may equal Y′ or it may be a different integer.

Once the pre-fixed row patterns are selected, the method 600 may loop back to the operation 614 for an additional check of the second floor plan 712. Operation 614, operation 616, and operation 618 may be performed iteratively to increment through different row patterns to find a row pattern that results in adequate row balancing and is below the critical row density threshold for the second floor plan 712. In some embodiments, the pre-fixed row patterns are fixed with a matching row pattern for each cell height. In some embodiments, a third floor plan is generated using the same or similar operations of the method 600.

At the operation 620, the row regions are finalized. The density for the region after the changes to the selected pre-fixed row patterns is now less than the critical density threshold. Additional checks, such as DRC for the IC 100, may be performed. In some embodiments, routing checks may be performed.

At the operation 622, the one or more modified rows 750 are generated based on the selected pre-fixed row patterns to form the second floor plan 712. In some embodiments, the region is populated with the selected pre-fixed row patterns to generate the one or more modified rows 750. The one or more modified rows 750 may be generated as a function of operation 312.

In some embodiments, the row pattern 718, 720, or 722 may be formed using X″ first rows and Y″ first rows. In some embodiments, X″≠X′ and Y″≠Y′. The row patterns 718, 720, or 722 are then X″:Y″.

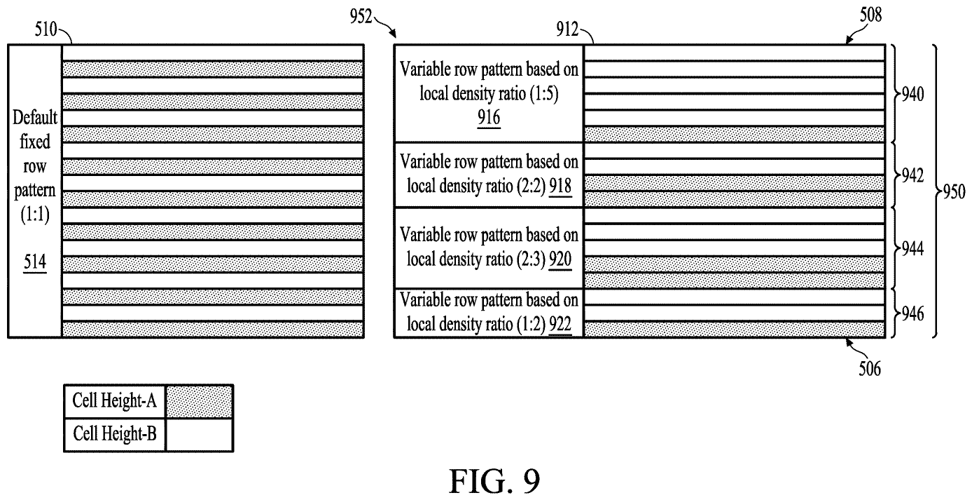

FIG. 8 illustrates an additional example method 800 for generating one or more modified rows 950 to modify the first floor plan 510 to generate an example second floor plan 912 of FIG. 9. FIG. 8 may be performed as further operations of the operation 312. In this embodiment, the method 800 includes an operation 810, an operation 812, an operation 814, an operation 816, an operation 818, an operation 820, and an operation 822. The method 800 may be used to generate the second floor plan 912 with non-uniform row patterns with different number of rows for each cell height. The method 800 may be performed by a circuit fabricator system.

FIG. 9 illustrates the first floor plan 510 being modified to generate the second floor plan 912. The second floor plan 912 includes a local region 940, a local region 942, a local region 944, and a local region 946. The local region 940 includes a row pattern 916, the local region 942 includes a row pattern 918, the local region 944 includes a row pattern 920, and the row region 946 includes a row pattern 922 to form one or more row patterns 952.

The operation 810, the operation 812, and the operation 814 involve the same or similar functions and features of the operation 610, the operation 612, and the operation 614, respectively. At the operation 816, a number of rows for a height of the first cell height A and the second cell height B is calculated based on constraints. These constraints may include area constraints, cell area constraints, density constraints, or other constraints associated with the IC 100. In some embodiments, density constraints specify the number of cells that must be present in a region, such as the local region 940, the local region 942, the local region 944, or the local region 946. In some embodiments, the density constraint is the critical row density threshold.

Further, the operation 816 may include determining the one or more row patterns 952, which may vary. The one or more row patterns 952 may a default fixed row pattern of 1:1 of the first floor plan 510 to generate the second floor plan 912. That is the plurality of first rows 506 and the plurality of second rows 508 are placed to form the one or more modified rows 950. Once completed, the method 800 proceeds to the operation 818. The calculated number of rows for each cell height of one or more is checked to ensure the calculated number of rows for the height of the first cell height A and the second cell height B meets the density constraint. For example, the X′ first rows and the Y′ second rows are calculated for the X′ zone and the Y′ zone of each of the row pattern 916, the row pattern 918, the row pattern 920, and the row pattern 922. The row pattern 916, the row pattern 918, the row pattern 920, and the row pattern 922 are then calculated as X′:Y′, X″:Y″, X″″:Y′″″, and X″″:Y″″, where X′:Y′=1:5, X″:Y″=2:2, X′″:Y′″=2:3, and X″″:Y″″=1:3 In some embodiments, X′:Y′≠X″:Y″, X′″:Y″, and/or X′″: Y′″. In some embodiments, X″:Y″≠X′″:Y′″ and/or X″″:Y″″. In some embodiments, X′″:Y′″≠X″″:Y″″″″.

The local region 940, the local region 942, the local region 944, and the local region 946 are finalized once it is determined that the density constraint is met at the operation 820. The density for the local region 940, the local region 942, the local region 944, and the local region 946 after changing rows to the one or more modified rows 950 is now less than the critical density threshold. Operation 820 may include the same or similar functions as the operation 620. The operation 814, The operation 816, and the operation 818 may be performed iteratively to increment through different row patterns for different regions. In some embodiments, these operations are performed until the critical density threshold is met and the rows are adequately balanced. In some embodiments, a row patterns between a first cell height, a second cell height, and a third cell height are calculated.

At the operation 822, the one or more modified rows 922 are generated based on the calculated number of rows for the height of the first cell height A and the second cell height B within the local region 940, the local region 942, the local region 944, and the local region 946 to form the second floor plan 912. In some embodiments, the one or more modified rows replace rows of the first floor plan 510 to form the second floor plan 912. The one or more modified rows may be generated as a function of operation 312.

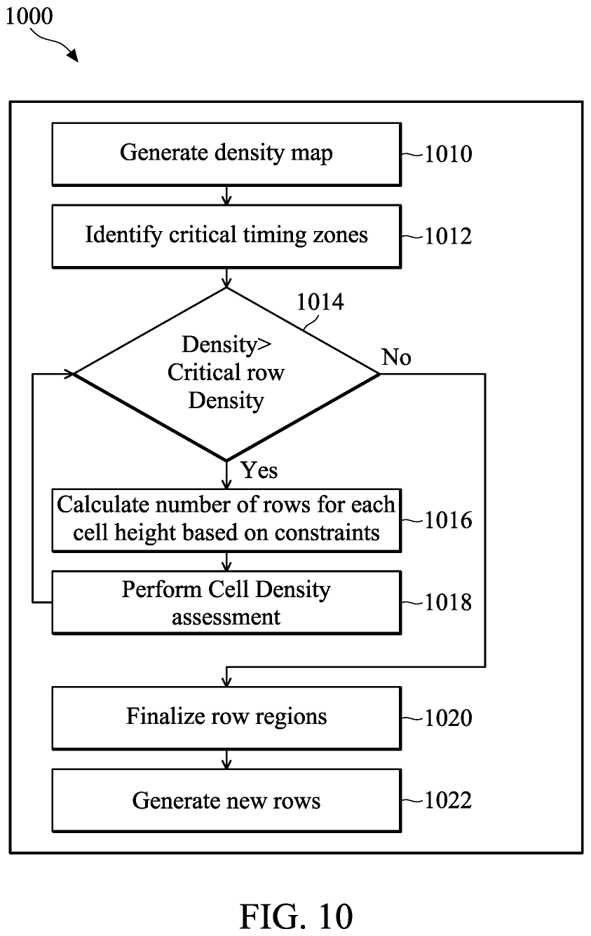

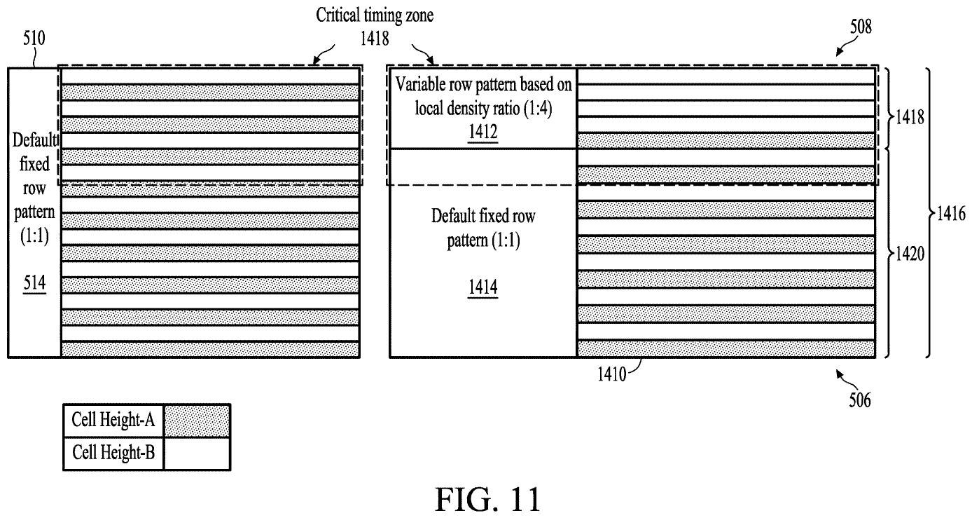

FIG. 10 illustrates an additional example method 1000 for generating one or more modified rows 1416 to modify the first floor plan 510 to generate an example second floor plan 1410 of FIG. 11. FIG. 10 may be performed as further operations of the operation 312. In this embodiment, the method 1000 includes an operation 1010, an operation 1012, an operation 1014, an operation 1016, an operation 1018, an operation 1020, and an operation 1022. The method 1000 may be used to generate the second floor plan 1410 with non-uniform row patterns with different number of rows for each cell height. The method 1000 may be performed by a circuit fabricator system.

FIG. 11 illustrates the first floor plan 510 being modified to generate the second floor plan 1410. The second floor plan 1410 includes a local region 1418 and a local region 1420 that form the one or more modified rows 1416. The local region 1418 includes a row pattern 1412 and the local region 1420 includes a row pattern 1414.

The method 1000 determines floor plans that satisfy the critical row density and improve critical timing paths within the floor plan. For example, a critical timing zone 1418 may include cells that are segments of an important timing path of the IC 100. In some embodiments, a timing performance of the IC 100 heavily depends on the critical timing zone 1418. To satisfy the timing requirement and the critical row density, the method 1000 converts the first floor plan 510 to the second floor plan 1410.

The operation 1010, the operation 1014, the operation 1018, the operation 1020, and the operation 1022 involve the same or similar functions and features of the operation 810, the operation 814, the operation 818, the operation 820, and the operation 822, respectively. At the operation 1012, the critical timing zone 1418 is identified. In some embodiments, additional critical timing zones are identified. Further, the critical timing zone 1418 may be identified based on a timing requirement or other performance criteria.

At the operation 1016, the number of rows for the first cell height A and the second cell height B are calculated based on constraints. In some embodiments, the constraints are the critical row density and the timing requirement. In an example, the local region 1418 with the row pattern 1418 and the local region 1420 with the row pattern 1414 are calculated. The second floor plan 1410 results from the changes. Based on the changes, the second floor plan 1410 meets the critical row density for each cell height and the timing requirement for the IC 100. In some embodiments, different row patterns are calculated. In addition, additional local regions may be determined based on other critical timing zones.

In some embodiments, fabricated circuits generated using one of the discussed methods 300, 400, 600, 800, and/or 1000 have better performance. For example, the circuits have better leakage performance after row balancing by using a hybrid row design with variable row patterns. Further, the circuits include improved frequency performance improved leakage performance. In some embodiments, the leakage improves between 5-8%. In some embodiments, the frequency improves 0.5-2%.

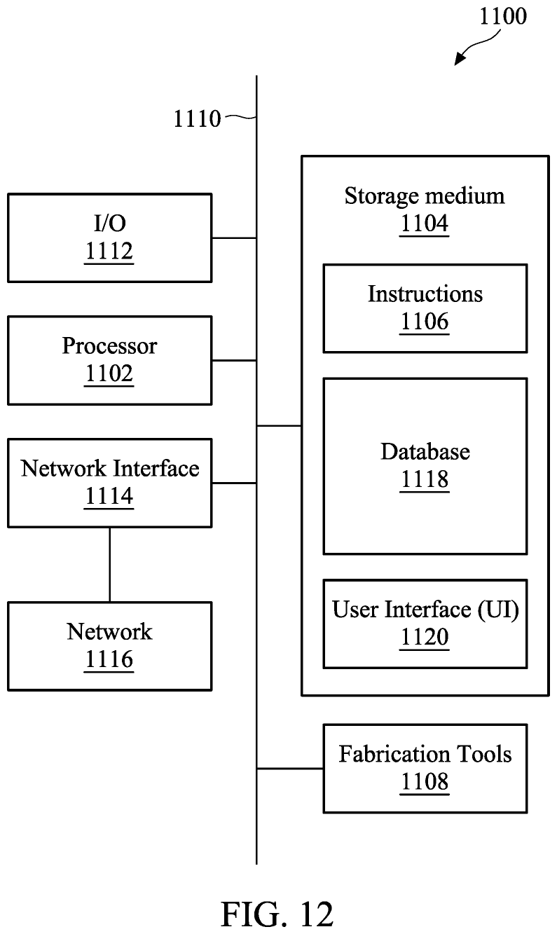

FIG. 12 is a block diagram schematically illustrating an example of a computer system 1100 configured to provide the devices, including electronic devices and semiconductor devices, and methods of the current disclosure, in accordance with some embodiments. Some or all the design, layout, and manufacture of the semiconductor devices, also referred to as semiconductor circuits, can be performed by or with the aid of the computer system 1100. Also, some or all the design, layout, and manufacture of the devices including electronic devices can be performed by or with the aid of the computer system 1100. In some embodiments, the computer system 1100 includes an electronic design automation (EDA) system. In some embodiments, the semiconductor devices are ICs.

In some embodiments, the system 1100 is a general-purpose computing device including a processor 1102 and a non-transitory, computer-readable storage medium 1104. The computer-readable storage medium 1104 may be encoded with, e.g., store, computer program code such as executable instructions 1106. Execution of the instructions 1106 by the processor 1102 provides (at least in part) a design tool that implements a portion or all the functions of the system 1100, such as pre-layout simulations, post-layout simulations, routing, rerouting, and final layout for manufacturing. Further, fabrication tools 1108 are included to further layout and physically implement the design and manufacture of the semiconductor devices. In some embodiments, execution of the instructions 1106 by the processor 1102 provides (at least in part) a design tool that implements a portion or all the functions of the system 1100. In some embodiments, the system 1100 includes a commercial router. In some embodiments, the system 1100 includes an automatic place and route (APR) system.

The processor 1102 is electrically coupled to the computer-readable storage medium 1104 by a bus 1110 and to an I/O interface 1112 by the bus 1110. A network interface 1114 is also electrically connected to the processor 1102 by the bus 1110. The network interface 1114 is connected to a network 1116, so that the processor 1102 and the computer-readable storage medium 1104 can connect to external elements using the network 1116. The processor 1102 is configured to execute the computer program code or instructions 1106 encoded in the computer-readable storage medium 1104 to cause the system 1100 to perform a portion or all the functions of the system 1100, such as providing the semiconductor devices and methods of the current disclosure and other functions of the system 1100. In some embodiments, the processor 1102 is a central processing unit (CPU), a multi-processor, a distributed processing system, an application specific integrated circuit (ASIC), and/or a suitable processing unit.

In some embodiments, the computer-readable storage medium 1104 is an electronic, magnetic, optical, electromagnetic, infrared, and/or semiconductor system or apparatus or device. For example, the computer-readable storage medium 1104 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 1104 can include a compact disk read only memory (CD-ROM), a compact disk read/write memory (CD-R/W), and/or a digital video disc (DVD).

In some embodiments, the computer-readable storage medium 1104 stores computer program code or instructions 1106 configured to cause the system 1100 to perform a portion or all the functions of the system 1100. In some embodiments, the computer-readable storage medium 1104 also stores information which facilitates performing a portion or all the functions of the system 1100. In some embodiments, the computer-readable storage medium 1104 stores a database 1118 that includes one or more of component libraries, digital circuit cell libraries, and databases.

The system 1100 includes the I/O interface 1112, which is coupled to external circuitry. In some embodiments, the I/O interface 1112 includes a keyboard, keypad, mouse, trackball, trackpad, touchscreen, and/or cursor direction keys for communicating information and commands to the processor 1102.

The network interface 1114 is coupled to the processor 1102 and allows the system 1100 to communicate with the network 1116, to which one or more other computer systems are connected. The network interface 1114 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 1100 can be performed in two or more systems that are like system 1100.

The system 1100 is configured to receive information through the I/O interface 1112. The information received through the I/O interface 1112 includes one or more of instructions, data, design rules, libraries of components and cells, and/or other parameters for processing by the processor 1102. The information is transferred to the processor 1102 by the bus 1110. Also, the system 1100 is configured to receive information related to a user interface (UI) through the I/O interface 1112. This UI information can be stored in the computer-readable storage medium 1104 as a UI 1120.

In some embodiments, a portion or all the functions of the system 1100 are implemented via a standalone software application for execution by a processor. In some embodiments, a portion or all the functions of the system 1100 are implemented in a software application that is a part of an additional software application. In some embodiments, a portion or all the functions of the system 1100 are implemented as a plug-in to a software application. In some embodiments, at least one of the functions of the system 1100 is implemented as a software application that is a portion of an EDA tool. In some embodiments, a portion or all the functions of the system 1100 are implemented as a software application that is used by the system 1100. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 1100 include fabrication tools 1108 for implementing the manufacturing processes of the system 1100. For example, based on the final layout, photolithographic masks may be generated, which are used to fabricate the semiconductor device by the fabrication tools 1108.

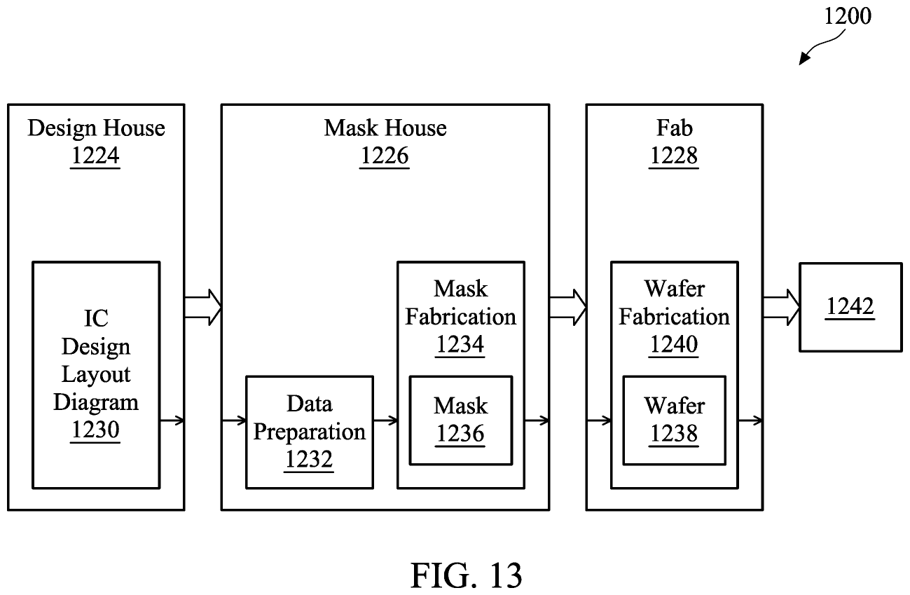

Further aspects of device fabrication are disclosed in conjunction with FIG. 13, which is a block diagram of a semiconductor device manufacturing system 1200 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 1200.

In FIG. 13, the semiconductor device manufacturing system 1200 includes entities, such as a design house 1224, a mask house 1226, and a semiconductor device manufacturer/fabricator (“Fab”) 1228, that interact with one another in the design, development, and manufacturing cycles and/or services related to manufacturing a semiconductor device, such as the semiconductor devices described herein. The entities in the system 1200 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 1224, the mask house 1226, and the semiconductor device fab 1228 are owned by a single larger company. In some embodiments, two or more of the design house 1224, the mask house 1226, and the semiconductor device fab 1228 coexist in a common facility and use common resources.

The design house (or design team) 1224 generates a semiconductor device design layout diagram 1230. The semiconductor device design layout diagram 1230 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 1230 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 1224 implements a design procedure to form a semiconductor device design layout diagram 1230. The semiconductor device design layout diagram 1230 is presented in one or more data files having information of the geometrical patterns. For example, semiconductor device design layout diagram 1230 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 1226 includes data preparation 1232 and mask fabrication 1234. The mask house 1226 uses the semiconductor device design layout diagram 1230 to manufacture one or more masks 1236 to be used for fabricating the various layers of the semiconductor device or semiconductor structure. The mask house 1226 performs mask data preparation 1232, where the semiconductor device design layout diagram 1230 is translated into a representative data file (RDF). The mask data preparation 1232 provides the RDF to the mask fabrication 1234. The mask fabrication 1234 includes a mask writer that converts the RDF to an image on a substrate, such as a mask (reticle) 1236 or a semiconductor wafer 1238. The design layout diagram 1230 is manipulated by the mask data preparation 1232 to comply with characteristics of the mask writer and/or criteria of the semiconductor device fab 1228. In FIG. 13, the mask data preparation 1232 and the mask fabrication 1234 are illustrated as separate elements. In some embodiments, the mask data preparation 1232 and the mask fabrication 1234 can be collectively referred to as mask data preparation.

In some embodiments, the mask data preparation 1232 includes an optical proximity correction (OPC) which uses lithography enhancement techniques to compensate for image errors, such as those that can arise from diffraction, interference, other process effects and the like. The OPC adjusts the semiconductor device design layout diagram 1230. In some embodiments, the mask data preparation 1232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1232 includes a mask rule checker (MRC) that checks the semiconductor device design layout diagram 1230 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 1230 to compensate for limitations during the mask fabrication 1234, which may undo part of the modifications performed by OPC to meet mask creation rules.

In some embodiments, the mask data preparation 1232 includes lithography process checking (LPC) that simulates processing that will be implemented by the semiconductor device fab 1228. LPC simulates this processing based on the semiconductor device design layout diagram 1230 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are to be repeated to further refine the semiconductor device design layout diagram 1230.

The above description of mask data preparation 1232 has been simplified for the purposes of clarity. In some embodiments, data preparation 1232 includes additional features such as a logic operation (LOP) to modify the semiconductor device design layout diagram 1230 according to manufacturing rules. Additionally, the processes applied to the semiconductor device design layout diagram 1230 during data preparation 1232 may be executed in a variety of different orders.

After the mask data preparation 1232 and during the mask fabrication 1234, a mask 1236 or a group of masks 1236 are fabricated based on the modified semiconductor device design layout diagram 1230. In some embodiments, the mask fabrication 1234 includes performing one or more lithographic exposures based on the semiconductor device design layout diagram 1230. In some embodiments, an electron-beam (e-beam) or a mechanism of multiple e-beams is used to form a pattern on a mask (photomask or reticle) 1236 based on the modified semiconductor device design layout diagram 1230. The mask 1236 can be formed in various technologies. In some embodiments, the mask 1236 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 1236 includes a transparent substrate (e.g., fused quartz) and an opaque material (e.g., chromium) coated in the opaque regions of the binary mask. In another example, the mask 1236 is formed using a phase shift technology. In a phase shift mask (PSM) version of the mask 1236, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1234 is used in a variety of processes. For example, such a mask(s) is used in an ion implantation process to form various doped regions in the semiconductor wafer 1238, in an etching process to form various etching regions in the semiconductor wafer 1238, and/or in other suitable processes.

The semiconductor device fab 1228 includes wafer fabrication 1240. The semiconductor device fab 1228 is a semiconductor device fabrication business that includes one or more manufacturing facilities for the fabrication of a variety of different semiconductor device products. In some embodiments, the semiconductor device fab 1228 is a semiconductor foundry. For example, there may be a manufacturing facility for the front end of line (FEOL) fabrication of a plurality of semiconductor device products, while a second manufacturing facility may provide the BEOL fabrication for the interconnection and packaging of the semiconductor device products, and a third manufacturing facility may provide other services for the foundry business.

The semiconductor device fab 1228 uses the mask(s) 1236 fabricated by the mask house 1226 to fabricate the semiconductor structures or semiconductor devices 1242 of the current disclosure. Thus, the semiconductor device fab 1228 at least indirectly uses the semiconductor device design layout diagram 1230 to fabricate the semiconductor structures or semiconductor devices 1242 of the current disclosure. Also, the semiconductor wafer 1238 includes a silicon substrate or other proper substrate having material layers formed thereon, and the semiconductor wafer 1238 further includes one or more of various doped regions, dielectric features, multilevel interconnects, and the like (formed at subsequent manufacturing steps). In some embodiments, the semiconductor wafer 1238 is fabricated by the semiconductor device fab 1228 using the mask(s) 1236 to form the semiconductor structures or semiconductor devices 1242 of the current disclosure. In some embodiments, the semiconductor device fabrication includes performing one or more lithographic exposures based at least indirectly on the semiconductor device design layout diagram 1230.

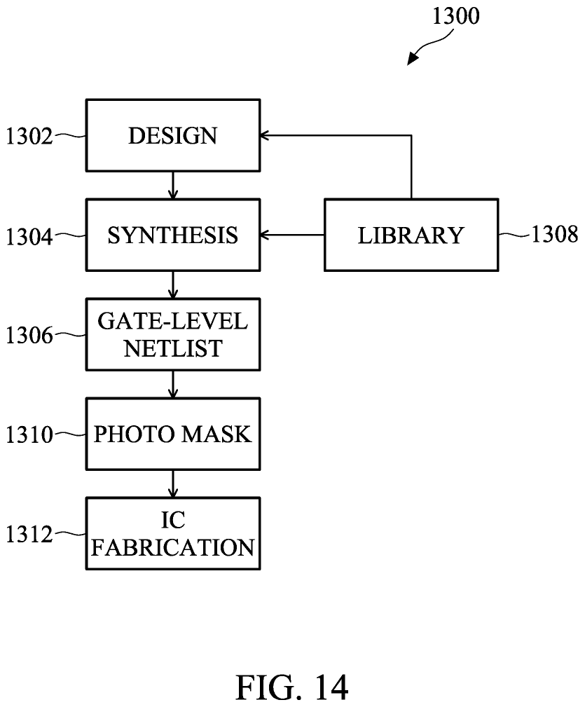

FIG. 14 generally illustrates an example integrated circuit design and fabrication process 1300 that may be implemented by the processing system 1100 for generating a physical layout from a user supplied behavioral/functional design. The user design 1302 specifies the desired behavior or function of the circuit based upon various signals or stimuli applied to the inputs of the overall design, and may be written in a suitable programming language. The design 1302 may be uploaded into the processor 1302 through the I/O interface 1102 by a user. Alternatively, the design 1302 may be uploaded and/or saved on the storage medium 1104, or the design 1302 may be uploaded through the network interface 1114 from a remote user.

A synthesis 1304 is performed on the design, in which the behavior and/or functions desired from the design 1302 are transformed to a functionally equivalent logic gate-level circuit description by matching the design to standard cells, such as from one or more cell libraries 1308. The cell library 1308 contains a listing of pre-designed components, or cells, each of which may perform a discrete logic function. The cells are stored in the cell library 1308 as information comprising internal circuit elements, the various connections to these circuit elements, a pre-designed physical layout pattern that includes the unit height of each cell along with the cell's designed power rails, dopant implants, wells, etc. Additionally, the stored cell may also comprise a shape of the cell, terminal positions for external connections, delay characteristics, power consumption, etc. The synthesis 1304 results in a functionally equivalent logic gate-level circuit description, such as a gate-level netlist 1306. The cell library 1308 may be stored, for example, in the database 1118. Based on the gate-level netlist 1306, a photolithographic mask 1310 may be generated, which is used to fabricate the integrated circuit 1312.

In an example, an example method, includes generating a first floor plan for an integrated circuit including a first plurality of first rows of a first cell height and a second plurality of second rows of a second cell height. Generating the first floor plan includes organizing the plurality of first rows and the plurality of second rows in a first row pattern. The first row pattern has X first rows and Y second rows where X and Y are positive integers. The method further includes modifying the first floor plan based on a predetermined cell density of first cells having the first cell height and second cells having the second cell height to generate a second floor plan. Modifying the first floor plan includes organizing the plurality of first rows and the plurality of second rows in a second row pattern. The second row pattern have X′ first rows and Y′ second rows where X′ and Y′ are positive integers. Modifying the first floor plan further includes placing the X′ first rows directly adjacent one another in a X′ zone and placing the Y′ second rows directly adjacent one another in a Y′ zone, and placing the X′ zone directly adjacent the Y′ zone. X:Y≠X′:Y′, X:Y equals the number of X first rows placed for every Y second rows, and X′:Y′ equals the number of X′ first rows placed for every Y′ second rows.

In an example floor plan for an integrated circuit includes a first region including X first rows of a first cell, where X is a positive integer, and Y second rows of a second cell height placed directly adjacent to the X first rows. X=Y. The floor plan further includes a second region including a X′ zone including X′ first rows. The X′ first rows are placed adjacently within the X′ zone. The second region further includes a Y′ zone including Y′ second rows. The Y′ second rows are placed adjacently within the Y′ zone. The X′ zone is placed adjacent to the Y′ zone, X′≠Y′, the X′ first rows and the Y′ second rows are placed to form a X′:Y′ ratio, and X′:Y′ equals the number of X′ first rows placed for every Y′ second rows. In an additional example, an example system for generating an integrated circuit includes a non-transitory computer readable medium configured to store instructions thereon and a processor connected to the non-transitory computer readable medium. The processor is configured to execute the instructions for generating a density and congestion map for a region of the integrated circuit, generating a density region for the region of the integrated circuit, and determining whether the region satisfies predetermined design rules. Responsive to determining the region fails to satisfy the predetermined design rules, the processor is further configured to execute the instructions for calculating one or more row patterns for the region. Each of one or more row patterns include a plurality of X first rows of a first cell height and a plurality of Y second rows of a second cell height, X and Y equaling positive integers. The plurality of X first rows and the plurality of Y second rows are organized in a first row pattern of X:Y. X first rows are placed adjacently in an X zone, and Y second rows are placed adjacently in a Y zone, the X zone is adjacently placed to the Y zone, the X first rows does not equal the Y second rows, and X:Y equals the number of X first rows placed for every Y second rows. Responsive to determining the region fails to satisfy the predetermined design rules, the processor is further configured to execute the instructions for selecting one or more pre-fixed row patterns that match the one or more row patterns including the X:Y ratio. The processor is further configured to execute the instructions for finalizing the region including selected pre-fixed row patterns and generating new rows with the selected pre-fixed row patterns.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
generating a first floor plan for an integrated circuit including a first plurality of first rows of a first cell height and a second plurality of second rows of a second cell height, wherein generating the first floor plan includes:
organizing the plurality of first rows and the plurality of second rows in a first row pattern, the first row pattern having X first rows and Y second rows where X and Y are positive integers;
modifying the first floor plan based on a predetermined cell density of first cells having the first cell height and second cells having the second cell height to generate a second floor plan, including:
organizing the plurality of first rows and the plurality of second rows in a second row pattern, the second row pattern having X′ first rows and Y′ second rows where X′ and Y′ are positive integers;
placing the X′ first rows directly adjacent one another in a X′ zone; and
placing the Y′ second rows directly adjacent one another in a Y′ zone;
placing the X′ zone directly adjacent the Y′ zone; and
wherein X:Y≠X′:Y′.

2. The method of claim 1, wherein modifying the first floor plan includes:
receiving a netlist area from a netlist, the netlist area equaling a maximum total area that can be occupied by cells of the first cell height and cells of the second cell height;
calculating cell areas for the first cells and the second cells based on the netlist area;
calculating the second row pattern for one or more row regions; and
generating the second floor plan including the X′ first rows and the Y′ second rows based on the second row pattern.

3. The method of claim 2, further comprising calculating a floor plan size for the second floor plan.

4. The method of claim 3, wherein the floor plan size for the second floor plan is calculated according to
$$Second Floor Plan Size = \frac{( Netlist AreaA + Netlist AreaB )}{T U}$$
where Netlist AreaA is a netlist area of the first cells, Netlist AreaB is a netlist area of the second cells, and TU is target utilization.

5. The method of claim 2, wherein generating the second floor plan includes:
manufacturing an integrated circuit based on the second floor plan.

6. The method of claim 2, wherein generating the one or more modified rows further includes:
rerouting lower layers based on the second floor plan.

7. The method of claim 2, wherein the second row pattern of X:Y is one of 1:2, 1:3, 1:4, 2:3, or 3:4.

8. The method of claim 1, wherein modifying the first floor plan includes:
generating a density and congestion map for a region of the integrated circuit;
generating a density region for the region of the integrated circuit;
determining whether the density is greater than the selected cell density;
responsive to determining the density is greater than the selected cell density:
calculating the second row pattern for the region, and
selecting one or more pre-fixed row patterns that match the second row pattern;
finalizing the region including selected pre-fixed row patterns that match the second row pattern; and
generating the one or more modified rows based on the one or more pre-fixed row patterns to form the second floor plan.

9. The method of claim 8, wherein the one or more pre-fixed row patterns of X:Y include at least one of 1:2, 1:3, 1:4, 2:3, or 3:4.

10. The method of claim 8, wherein the density region is based on a selected number of rows, a selected height, and the one or more pre-fixed row patterns.

11. A floor plan for an integrated circuit, comprising:
a first region including:
X first rows of a first cell height;
Y second rows of a second cell height placed directly adjacent to the X first rows, where X and Y are a positive integers;
a second region including:
a X′ zone including X′ of the first rows, the X′ first rows placed adjacently within the X′ zone;
a Y′ zone including Y′ of the second rows, the Y′ second rows placed adjacently within the Y′ zone; and
wherein the X′ zone is placed adjacent to the Y′ zone, X′≠Y′, and X:Y+X′:Y′.

12. The floor plan of claim 11, further comprising:
a third region including:
a X″ zone including X″ of the first rows, the X″ first rows placed adjacently within the X″ zone;
a Y″ zone including Y″ of the second rows, the Y″ second rows placed adjacently within the Y″ zone; and
wherein the X″ zone is placed adjacent to the Y″ zone, X″≠Y″, and X″:Y″≠X′/Y′.

13. The floor plan of claim 11, wherein the X:Y is 1:1, 2:2, or 3:3.

14. The floor plan of claim 11, wherein the X′:Y′ is 1:2, 1:3, 1:4, 2:3, 2:4 or 3:4.

15. The floor plan of claim 11, wherein the first region and the second region satisfy a utilization ratio threshold.

16. The floor plan of claim 11, wherein the floor plan includes a floor plan size.

17. The floor plan of claim 16, wherein the floor plan size is calculated according to
$$Floor Plan Size = \frac{( Netlist AreaA + Netlist AreaB )}{T U}$$
where Netlist AreaA is a netlist area of the first cells, Netlist AreaB is a netlist area of the second cells, and TU is target utilization.

18. A system for generating an integrated circuit, the system comprising:
a non-transitory computer readable medium configured to store instructions thereon; and
a processor connected to the non-transitory computer readable medium, wherein the processor is configured to execute the instructions for:
generating a density and congestion map for a region of the integrated circuit;
generating a density region for the region of the integrated circuit;
determining whether the region satisfies predetermined design rules;
responsive to determining the region fails to satisfy the predetermined design rules:
calculating one or more row patterns for the region, each of one or more row patterns including a plurality of X first rows of a first cell height and a plurality of Y second rows of a second cell height, where X and Y are positive integers, the plurality of X first rows and the plurality of Y second rows organized in a first row pattern having a ratio of X:Y, wherein the X first rows are placed adjacently in an X zone, and the Y second rows are placed adjacently in a Y zone, the X zone is adjacently placed to the Y zone, the X first rows does not equal the Y second rows; and
selecting one or more pre-fixed row patterns that match the one or more row patterns including the X:Y ratio;
finalizing the region including selected pre-fixed row patterns.

19. The system of claim 18, wherein the density region is based on a selected number of rows, a selected height, and the one or more pre-fixed row patterns.

20. The system of claim 18, wherein the processor is further configured to execute the instructions for manufacturing an integrated circuit according to a second floor plan.
